(19) United States
(12) Patent Application Publication
(10) Pub. No.: US 2014/0049870 A1
(43) Pub. Date: Feb. 20, 2014

(54) SEMICONDUCTOR MODULE

(71) Applicant: Sumitomo Electric Industries, Ltd., Osaka-shi (JP)

(72) Inventor: Kazuhiro FUJIKAWA, Osaka-shi (JP)

(73) Assignee: Sumitomo Electric Industries, Ltd., Osaka-shi (JP)

(21) Appl. No.: 13/954,521

(22) Filed: Jul. 30, 2013

Related U.S. Application Data
(60) Provisional application No. 61/683,091, filed on Aug. 14, 2012.

(30) Foreign Application Priority Data
Aug. 14, 2012 (JP) 2012-179764

(51) Int. Cl. H01L 27/02

(52) U.S. Cl. CPC H01L 27/0266
USPC 361/101

(57) ABSTRACT

A semiconductor module in accordance with one embodiment comprises a plurality of semiconductor switching devices; a plurality of control circuits provided for the respective semiconductor switching devices and adapted to control switching of the semiconductor switching devices corresponding thereto and perform protection actions to stop switching the semiconductor switching devices corresponding thereto falling into a control stop state; and a signal path connecting the plurality of control circuits to each other and transmitting among the plurality of control circuits a protection action signal indicating whether or not there is the protection action for each of the semiconductor switching devices corresponding to the plurality of control circuits. Any of the plurality of control circuits receiving the protection action signal indicating that another control circuit is in the protection action through the signal path stops switching the semiconductor switching device corresponding thereto.

### CROSS-REFERENCE TO RELATED APPLICATIONS

This application claims priority to Provisional Application Ser. No. 61/683,091, filed on Aug. 14, 2012 and claims the benefit of Japanese Patent Application No. 2012-179764, filed on Aug. 14, 2012, all of which are incorporated herein by reference in their entirety.

### BACKGROUND

1. Field

The present invention relates to a semiconductor module.

2. Description of the Related Art

As an example of semiconductor modules, an intelligent power module (IPM) has been known (see, for example, Non Patent Literature 1: IPM L1/S1-Series Application Note [online]. Mitsubishi Electric Corporation, September, 2008 [retrieved on May 30, 2012]. Retrieved from the Internet: <URL: http://www.mitsubishielectric.co.jp/semiconductors/files/manuals/ipm_{—}11_s1_note_j.pdf>.). The IPM comprises a plurality of semiconductor switching devices such as MOSFET and IGBT, while respective control circuits are provided for the plurality of semiconductor switching devices. The plurality of control circuits in the IPM control switching of their corresponding semiconductor switching devices and perform protection actions to stop switching the semiconductor switching devices when they are in abnormal states.

### SUMMARY

In the technique described in Non Patent Literature 1, when one control circuit performs a protection action to stop switching its corresponding semiconductor switching device, a protection action signal indicating the protection action on-state is issued to an external circuit. In response to the protection action signal, the external circuit again feeds the IPM with such a signal as to stop switching a semiconductor switching device corresponding to another control circuit within the IPM.

Thus, for individually controlling protection actions of a plurality of control circuits in the IPM through an external circuit, it takes time and effort to design the external circuit. Further, since the external circuit is designed by someone (e.g., a user of the semiconductor module) different from the designer and manufacturer of the semiconductor module, the protection action may not be performed appropriately depending on how the external circuit is designed.

It is therefore an object of the present invention to provide a semiconductor module which, when control for a plurality of semiconductor switching devices is forcibly stopped, can stop actions of other semiconductor switching devices easily and more securely.

The semiconductor module in accordance with one aspect of the present invention comprises a plurality of semiconductor switching devices; a plurality of control circuits provided for the respective semiconductor switching devices and adapted to control switching of the semiconductor switching devices corresponding thereto and perform protection actions to stop switching the semiconductor switching devices corresponding thereto falling into a control stop state; and a signal path connecting the plurality of control circuits to each other and transmitting among the plurality of control circuit a protection action signal indicating whether or not there is the protection action for each of the semiconductor switching devices corresponding to the plurality of control circuits. Any of the plurality of control circuits receiving the protection action signal indicating that another control circuit is in the protection action through the signal path stops switching the semiconductor switching device corresponding thereto.

In this structure, a plurality of control circuits in the semiconductor module mutually cooperate, so as to perform protection actions for a plurality of semiconductor switching devices. As a result, when control for a plurality of semiconductor switching devices is forcibly stopped, actions of other semiconductor switching devices can be stopped easily and more securely.

Each of the plurality of control circuits may comprise an I/O circuit adapted to issue the protection action signal to the signal path and receive the protection action signal transmitted through the signal path. In this case, the signal path connects the I/O circuits of the plurality of control circuits in a bus topology.

As a consequence, the protection action signal of any of the plurality of control circuits can easily be transmitted to other control circuits through the signal path.

The plurality of semiconductor switching devices may include first and second semiconductor switching devices, sequentially connected in series between high- and low-voltage-side input terminals, having an intermediate node connected to a first output terminal and third and fourth semiconductor switching devices, sequentially connected in series between the high- and low-voltage-side input terminals, having an intermediate node connected to a second output terminal. In this case, the signal path may have a first path connecting respective control circuits corresponding to the first and second semiconductor switching devices to each other, a second path connecting respective control circuits corresponding to the third and fourth semiconductor switching devices to each other, and a third path connecting the first and second paths to each other on the side of the respective circuits corresponding to the second and fourth semiconductor switching devices. In such a structure, level-shift circuits may be provided on the first and second paths so as to be located closer to the respective control circuits corresponding to the first and third semiconductor switching devices than the third path.

Thus constructed semiconductor module having the first to fourth semiconductor switching devices can function as a single-phase full-bridge inverter, for example. It has level-shift circuits and thus allows a plurality of control circuits to securely transmit the protection action signal even when the control circuits corresponding to the second and fourth semiconductor switching devices on the low-voltage input terminal side and the control circuits corresponding to the first and third semiconductor switching devices on the high-voltage input terminal side have ground levels different from each other.

In thus constructed semiconductor module having the first to fourth semiconductor switching devices, the plurality of semiconductor switching devices may further include fifth and sixth semiconductor switching devices, sequentially connected in series between the high- and low-voltage-side input terminals, having an intermediate node connected to a third output terminal. In this case, the signal path may further have a fourth path connecting respective control circuits corresponding to the fifth and sixth semiconductor switching devices to each other. The third path may connect the first, second, and fourth paths on the side of the respective control circuits corresponding to the second, fourth, and sixth semiconductor switching devices. In such a structure, a level-shift circuit may be provided on the fourth path so as to be located closer to the control circuit corresponding to the fifth semiconductor switching device than the third path.

Thus constructed semiconductor module having the first to sixth semiconductor switching devices can function as a three-phase full-bridge inverter, for example. It has level-shift circuits and thus allows a plurality of control circuits to securely transmit the protection action signal even when the control circuits corresponding to the second, fourth, and sixth semiconductor switching devices on the low-voltage input terminal side and the control circuits corresponding to the first, third, and fifth semiconductor switching devices on the high-voltage input terminal side have ground levels different from each other.

The protection action signal may be a binary signal based on whether a voltage is high or low. In this case, the lower voltage signal in the binary signal may indicate that the protection action is on.

A mode where the protection action signal is a binary signal based on whether a voltage is high or low, while the low-voltage state indicates that the protection action is on, may employ a wired-OR structure.

The semiconductor module in accordance with one embodiment may further comprise an external I/O terminal connecting with one end of the signal path.

Using the external I/O terminal, an action stop function for the semiconductor module based on a cause outside of the semiconductor module such as a pushdown of an emergency stop button can easily be achieved.

As mentioned above, a semiconductor module which, when control for a plurality of semiconductor switching devices is forcibly stopped, can stop actions of other semiconductor switching devices easily and more securely can be provided.

### BRIEF DESCRIPTION OF THE DRAWING

FIG. 1 is a circuit diagram of the semiconductor module in accordance with an embodiment of the present invention.

### DETAILED DESCRIPTION

In the following, preferred embodiments of the present invention will be explained with reference to the drawing. In the explanation of the drawing, the same constituents will be referred to with the same signs while omitting their overlapping descriptions.

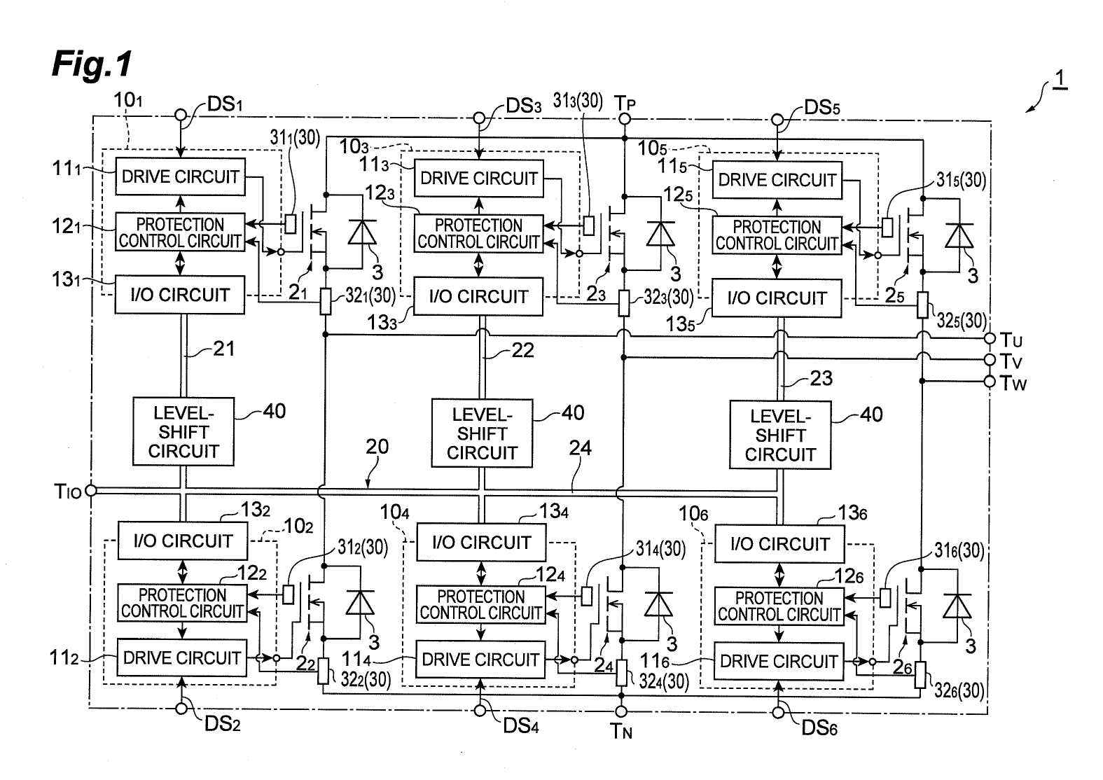

FIG. 1 is a circuit diagram of the semiconductor module in accordance with an embodiment of the present invention. The semiconductor module 1 illustrated in FIG. 1 is a three-phase full-bridge inverter (power converter circuit) as a power semiconductor module. The semiconductor module 1 converts a DC power fed between a high-voltage-side input terminal T_{P} and a low-voltage-side input terminal T_{N} into a three-phase AC power among first to third output terminals T_{U}, T_{V}, T_{W}. The semiconductor module 1 is a so-called intelligent power module (IPW).

The semiconductor module 1 comprises first to sixth semiconductor switching devices 2₁ to 2₆, first to sixth control circuits 10₁ to 10₆ provided so as to correspond to the first to sixth semiconductor switching devices 2₁ to 2₆, and a signal line (signal path) 20 which connects the first to sixth control circuits 10₁ to 10₆ to each other. An example of the first to sixth semiconductor switching devices 2₁ to 2₆ is a transistor. Examples of the transistor include MOSFET and IGBT. In the following explanation, the first to sixth control circuits 10₁ to 10₆ are MOSFETs unless otherwise specified.

The first and second semiconductor switching devices 2₁, 2₂ are sequentially connected in series between the high-voltage-side input terminal T_{P} and low-voltage-side input terminal T_{N}, while having an intermediate node connected to the first output terminal T_{U}.

More specifically, the drain and source terminals of the first semiconductor switching device 2₁ are electrically connected to the high-voltage-side input terminal T_{P} and the drain terminal of the second semiconductor switching device 2₂, respectively. The source terminal of the second semiconductor switching device 2₂ is electrically connected to the low-voltage-side input terminal T_{N}. The source terminal of the first semiconductor switching device 2₁ and the drain terminal of the second semiconductor switching device 2₂ are electrically connected to the first output terminal T_{U}. The gate terminals of the first and second semiconductor switching devices 2₁, 2₂ are electrically connected to the first and second control circuits 10₁, 10₂, respectively.

Similarly, the third and fourth semiconductor switching devices 2₃, 2₄ are sequentially connected in series between the high-voltage-side input terminal T_{P} and low-voltage-side input terminal T_{N}, while having an intermediate node connected to the second output terminal T_{V}.

More specifically, the drain and source terminals of the third semiconductor switching device 2₃ are electrically connected to the high-voltage-side input terminal T_{P} and the drain terminal of the fourth semiconductor switching device 2₄, respectively. The source terminal of the fourth semiconductor switching device 2₄ is electrically connected to the low-voltage-side input terminal T_{N}. The source terminal of the third semiconductor switching device 2₃ and the drain terminal of the fourth semiconductor switching device 2₄ are electrically connected to the second output terminal T_{V}. The gate terminals of the third and fourth semiconductor switching devices 2₃, 2₄ are electrically connected to the third and fourth control circuits 10₃, 10₄, respectively.

Similarly, the fifth and sixth semiconductor switching devices 2₅, 2₆ are sequentially connected in series between the high-voltage-side input terminal T_{P} and low-voltage-side input terminal T_{N}, while having an intermediate node connected to the third output terminal T_{W}.

More specifically, the drain and source terminals of the fifth semiconductor switching device 2₅ are electrically connected to the high-voltage-side input terminal T_{P} and the drain terminal of the sixth semiconductor switching device 2₆, respectively. The source terminal of the sixth semiconductor switching device 2₆ is electrically connected to the low-voltage-side input terminal T_{N}. The source terminal of the fifth semiconductor switching device 2₅ and the drain terminal of the sixth semiconductor switching device 2₆ are electrically connected to the third output terminal T_{W}. The gate terminals of the fifth and sixth semiconductor switching devices 2₅, 2₆ are electrically connected to the fifth and sixth control circuits 10₅, 10₆, respectively.

In the connection relationship mentioned above, the first to sixth semiconductor switching devices 2₁ to 2₆ can be divided into a semiconductor switching device group on the high-voltage-side input terminal T_{P} side, i.e., the first, third, and fifth semiconductor switching devices 2₁, 2₃, 2₅, and a semiconductor switching device group on the low-voltage-side input terminal T_{N} side, i.e., the second, fourth, and sixth semiconductor switching devices 2₂, 2₄, 2₆.

As illustrated in FIG. 1, respective anti-backflow diodes 3 may be connected to the first to sixth semiconductor switching devices 2₁ to 2₆. Specifically, the source terminals of the first to sixth semiconductor switching devices 2₁ to 2₆ are connected to the anodes of their corresponding diodes 3, while the drain terminals of the first to sixth semiconductor switching devices 2₁ to 2₆ are connected to the cathodes of their corresponding diodes 3.

The semiconductor module 1 includes monitor circuits (monitor units) 30₁ to 30₆ for monitoring whether the first to sixth semiconductor switching devices 2₁ to 2₆ are in a normal or abnormal state. The monitor units 30 include temperature sensors 31₁ to 31₆ and current sensors 32₁ to 32₆ provided so as to correspond to the first to sixth semiconductor switching devices 2₁ to 2₆.

Examples of the temperature sensors 31₁ to 31₆ include diodes disposed on semiconductor chips serving as the first to sixth semiconductor switching devices 2₁ to 2₆.

An example of the current sensors 32₁ to 32₆ is a test resistance. When the current sensors 32₁ to 32₆ are test resistances, the current sensors 32₁, 32₃, 32₅ corresponding to the first, third, and fifth semiconductor switching devices 2₁, 2₃, 2₅ arranged on the upper arm side are connected in series between the respective intermediate nodes between the first, third, and fifth semiconductor switching devices 2₁, 2₃, 2₅ and the second, fourth, and sixth semiconductor switching devices 2₂, 2₄, 2₆ connected in series thereto and the source terminals of the first, third, and fifth semiconductor switching devices 2₁, 2₃, 2₅. The current sensors 32₂, 32₄, 32₆ corresponding to the second, fourth, and sixth semiconductor switching devices 2₂, 2₄, 2₆ arranged on the lower arm side are connected in series between the respective source terminals of the second, fourth, and sixth semiconductor switching devices 2₂, 2₄, 2₆ and the low-voltage-side input terminal T_{N}. The connection relationship of the current sensors 32₁ to 32₆ is not limited to an example thereof mentioned above as long as they can detect currents flowing from the source terminals of the first to sixth semiconductor switching devices 2₁ to 2₆. For example, the currents flowing from the source terminals of the first to sixth semiconductor switching devices 2₁ to 2₆ may be shunted appropriately, so as to be detected.

Results of sensing by the temperature sensors 31₁ to 31₆ and current sensors 32₁ to 32₆ in the above-mentioned monitor units 30₁ to 30₆ are fed to their corresponding first to sixth control circuits 10₁ to 10₆.

The first to sixth control circuits 10₁ to 10₆ are mutually connected by the signal line 20. The first to sixth control circuits 10₁ to 10₆ may be so-called IC chips. As illustrated in FIG. 1, the first to sixth control circuits 10₁ to 10₆ are connected in parallel through the signal line 20. That is, the signal line 20 connects the first to sixth control circuits 10₁ to 10₆ in a so-called bus topology.

The first to sixth control circuits 10₁ to 10₆ will be referred to as i-th control circuits 10ᵢ (where i is any of 1 to 6) in order to explain their structures. Similar notations will also be employed for constituents in the first to sixth control circuits 10₁ to 10₆, constituents corresponding to the first to sixth control circuits 10₁ to 10₆ in the semiconductor module 1, and the like.

The i-th control circuit 10ᵢ has a drive circuit (drive unit) 11ᵢ, a protection control circuit (protection control unit) 12ᵢ, and an I/O circuit (I/O unit) 13ᵢ.

The drive circuit 11ᵢ performs switching control for the i-th semiconductor switching device 2ᵢ in response to a drive signal DSᵢ. An example of the drive signal DSᵢ is a PWM signal.

When a signal (sensor signal) from the monitor unit 30ᵢ indicates an abnormal state of the i-th semiconductor switching device 2ᵢ, the protection control circuit 12ᵢ performs a protection action to control the drive circuit 11ᵢ so as to forcibly stop the switching control for the i-th semiconductor switching device 2ᵢ. By the abnormal state is meant that the state of the i-th semiconductor switching device 2ᵢ is outside of its safe operation region. Examples of the abnormal state include a case where the value of the temperature sensor 31ᵢ is higher than a predetermined value (overheat state) and a case where the value of the current sensor 32ᵢ is at a predetermined current value or higher (overcurrent state and/or short-circuit state). Whether the i-th semiconductor switching device 2ᵢ corresponding to the i-th control circuit 10ᵢ is in the abnormal state or not can be determined by comparing a signal from the monitor unit 30ᵢ, such as the temperature sensor 31ᵢ and current sensor 32ᵢ, with a predetermined value. The protection control circuit 12ᵢ transmits a protection action signal indicating whether or not the i-th semiconductor switching device 2ᵢ is in the protection action to the other control circuits through the I/O circuit 13ᵢ and signal line 20.

The protection action signal is a binary signal based on whether a voltage value is high or low. Specifically, lower and higher voltage states (Low- and High-level states) indicate the protection on-state and normal operation, respectively. Hence, the protection control circuit 12ᵢ transmits a Low-level state (Low-level signal) as a protection action signal indicating the protection action on-state to the other control circuits through the I/O circuit 13ᵢ and signal line 20.

When the signal (sensor signal) from the monitor unit 30ᵢ changes from a value indicating the abnormal state to a value indicating the normal state after performing the protection action, i.e., after forcibly stopping switching control for the i-th semiconductor switching device 2ᵢ, the protection control circuit 12ᵢ resumes the switching control for the i-th semiconductor switching device 2ᵢ. In this case, the protection control circuit 12ᵢ transmits a protection action signal indicating that the switching control is resumed to the other control circuits through the I/O circuit 13ᵢ and signal line 20. Specifically, the protection control circuit 12ᵢ transmits a protection action signal at the High level to the other control circuits through the I/O circuit 13ᵢ and signal line 20.

A case where the i-th semiconductor switching device 2ᵢ is in the abnormal state has been explained as an example in which the protection control circuit 12ᵢ performs a protection action. However, when the i-th control circuit 10ᵢ per se is in the abnormal state, the protection control circuit 12ᵢ also issues the protection action signal (Low-level signal) indicating the protection action on-state, while performing the protection action. Similarly, when recovering from the abnormal state, the i-th control circuit 10ᵢ per se transmits the protection action signal (Hi-level signal) indicating the protection action off-state to the other control circuits through the I/O circuit 13ᵢ and signal line 20, while resuming the switching control for the i-th semiconductor switching device 2ᵢ. An example of the abnormal state of the i-th control circuit 10ᵢ per se is a case where the voltage fed to the i-th control circuit 10ᵢ for driving (operating) the same is lower than a predetermined level.

Further, in response to the protection action signal from another control circuit, the protection control circuit 12ᵢ controls the protection action of the i-th semiconductor switching device 2ᵢ and the resuming of the switching control from the switching off-state.

Specifically, upon receiving the protection action signal at the Low level from any of other control circuits through the signal line 20 and I/O circuit 13ᵢ, the protection control circuit 12ᵢ stops the switching control for the i-th semiconductor switching device 2ᵢ. Upon receiving the protection signal at the Hi level from any of the other control circuits, on the other hand, the protection control circuit 12ᵢ resumes the switching control for the i-th semiconductor switching device 2ᵢ.

The I/O circuit 13ᵢ is a circuit, connected to the signal line 20, for inputting and outputting the protection action signal of the i-th control circuit 10ᵢ. The I/O circuit 13ᵢ includes I/O terminals for the protection action signal. The I/O circuit 13ᵢ transmits the protection action signal issued from the protection control circuit 12ᵢ to the other control circuits through the signal line 20. The I/O circuit 13ᵢ receives the protection action signal transmitted from another control circuit through the signal line 20 and feeds it to the protection control circuit 12ᵢ. Hence, the I/O circuits 13₁ to 13₆ and the signal line 20 constitute a signal transmission circuit for the protection action signal. The I/O circuit 13ᵢ may be equipped with a transistor, for example, in order to issue the Hi- and Low-level states of voltage as a binary signal to the signal line 20.

The signal line 20 connects the I/O circuits 13₁ to 13₆ in a bus topology. Specifically, the signal line 20 has a first connection line 21 for connecting the first control circuit 10₁ located on the upper arm side and the second control circuit 10₂ located on the lower arm side to each other, a second connection line 22 for connecting the third control circuit 10₃ located on the upper arm side and the fourth control circuit 10₄ located on the lower arm side to each other, a third connection line 23 for connecting the fifth control circuit 10₅ located on the upper arm side and the sixth control circuit 10₆ located on the lower arm side to each other, and a fourth connection line 24 for connecting the first to third connection lines 21 to 23. The fourth connection line 24 is provided on the lower arm side.

In other words, assuming the fourth connection line 24 provided on the lower arm side to be a main signal line, the I/O circuits 13₁ to 13₆ of the first to sixth control circuits 10₁ to 10₆ are connected to the main signal line through auxiliary signal lines. As a consequence, the first to sixth control circuits 10₁ to 10₆ are connected in parallel through the signal line 20.

On the first to third connection lines 21 to 23, level-shift circuits 40 may be provided so as to be located closer to the upper arm, i.e., closer to the first, third, and fifth control circuits 10₁, 10₃, 10₅, than the fourth connection line 24. The level-shift circuits 40 adjust the signal level of the protection action signal according to differences in ground level among the first, third, and fifth control circuits 10₁, 10₃, 10₅ located on the upper arm side and differences between the respective ground levels of the first, third, and fifth control circuits 10₁, 10₃, 10₅ located on the upper arm side and the ground level of the second, fourth, and sixth control circuits 10₂, 10₄, 10₆ located on the lower arm side. The ground level of the first control circuit 10₁ corresponds to the voltage level of the intermediate node between the first and second semiconductor switching devices 2₁, 2₂. The ground level of the third control circuit 10₃ corresponds to the voltage level of the intermediate node between the third and fourth semiconductor switching devices 2₃, 2₄. The ground level of the fifth control circuit 10₅ corresponds to the voltage level of the intermediate node between the fifth and sixth semiconductor switching devices 2₅, 2₆. The ground level of the second, fourth, and sixth control circuits 10₂, 10₄, 10₆ corresponds to the voltage level of the low-voltage-side input terminal T_{N}. The level-shift circuits 40 may constitute a part of the signal transmission circuit with the I/O circuits 13₁ to 13₆ and the signal line 20.

In one embodiment, the semiconductor module 1 may have an external I/O terminal T_{IO}, which is connected to one end of the signal line 20, e.g., one end of the fourth connection line 24, and feeds signals from/to an external circuit.

An example of actions of the semiconductor module 1 will now be explained. First, a state where the first to sixth semiconductor switching devices 2₁ to 2₆ are controllable will be explained. The state where the first to sixth semiconductor switching devices 2₁ to 2₆ are controllable is a case where the first to sixth semiconductor switching devices 2₁ to 2₆ are in the normal state while the first to sixth control circuits 10₁ to 10₆ are in the normal state.

For example, the first to sixth control circuits 10₁ to 10₆ control switching of the first to sixth semiconductor switching devices 2₁ to 2₆ according to drive signals DS₁ to DS₆, which are PWM signals fed from the external circuit to the first to sixth control circuits 10₁ to 10₆, respectively. In the set of first and second semiconductor switching devices 2₁, 2₂, for example, the first and second semiconductor switching devices 2₁, 2₂ are operated such that one of them is in the on-state while the other is in the off-state. By performing similar operations in the set of first and second semiconductor switching devices 2₁, 2₂, the set of third and fourth semiconductor switching devices 2₃, 2₄, and the set of fifth and sixth semiconductor switching devices 2₅, 2₆ at intervals of a 1/3 period of the three-phase AC power to be issued, the semiconductor module 1 converts the DC power fed between the high-voltage-side input terminal T_{P} and the low-voltage-side input terminal T_{N}, so as to generate the three-phase AC power among the first to third output terminals T_{U} to T_{W}.

The action of the semiconductor module 1 in the case where the first to sixth semiconductor switching devices 2₁ to 2₆ are in the control stop state will now be explained. By the case where the first to sixth semiconductor switching devices 2₁ to 2₆ are in the control stop state is meant that the first to sixth control circuits 10₁ to 10₆ per se are in the abnormal state, e.g., the first to sixth semiconductor switching devices 2₁ to 2₆ fall in the abnormal state and/or a voltage supplied to the first to sixth semiconductor switching devices 2₁ to 2₆ is lower than a predetermined level. Here, the case where the first to sixth semiconductor switching devices 2₁ to 2₆ are in the abnormal state will mainly be explained.

When abnormality occurs in the i-th semiconductor switching device 2ᵢ, its corresponding i-th control circuit 10ᵢ stops the switching control for the i-th semiconductor switching device 2ᵢ and transmits the protection action signal in the Low-level state to the other control circuits connected in a bus topology through the signal line 20. The m-th control circuit (where m is a number of 1 to 6 other than i) having received the protection action signal at the Low-level state stops switching control for its corresponding m-th semiconductor switching device 2ₘ.

When the abnormal state of the i-th semiconductor switching device 2ᵢ corresponding to the i-th control circuit 10ᵢ is eliminated, by contrast, the i-th control circuit 10ᵢ resumes the switching control for the i-th semiconductor switching device 2ᵢ and transmits the protection action signal in the High-level state to the other control circuits connected in a bus topology through the signal line 20. The m-th control circuit (where m is a number of 1 to 6 other than i) having received the protection action signal at the High-level state resumes the switching control for its corresponding m-th semiconductor switching device 2ₘ.

Hence, when the abnormal state occurs in one of the first to sixth semiconductor switching devices 2₁ to 2₆ in the semiconductor module 1, the first to sixth control circuits 10₁ to 10₆ arranged within the semiconductor module 1 can cooperate with each other, so as to forcibly turn off all of the first to sixth semiconductor switching devices 2₁ to 2₆. When the abnormal state generated in any of the first to sixth semiconductor switching devices 2₁ to 2₆ is eliminated, on the other hand, the switching control for the first to sixth semiconductor switching devices 2₁ to 2₆ can resume.

While a case where the first to sixth semiconductor switching devices 2₁ to 2₆ fall in the abnormal state in the control stop states has been explained in the foregoing among the control stop states of the first to sixth semiconductor switching devices 2₁ to 2₆, the protection action and recovery action in the case where the first to sixth control circuits 10₁ to 10₆ are in the abnormal state are similar thereto.

Thus, the first to sixth control circuits 10₁ to 10₆ cooperate with each other so as to perform protection actions for the first to sixth semiconductor switching devices 2₁ to 2₆, whereby it is not necessary for users of the semiconductor module 1 to separately prepare external circuits, predetermined programs, and the like for making the first to sixth control circuits 10₁ to 10₆ perform the protection actions. Therefore, the first to sixth semiconductor switching devices 2₁ to 2₆ can easily be protected.

Further, providing the first to sixth control circuits 10₁ to 10₆ that can cooperate with each other to perform protection actions for the first to sixth semiconductor switching devices 2₁ to 2₆ in the semiconductor module 1 enables more appropriate protection actions corresponding to characteristics of the semiconductor module 1, specific examples of which are characteristics of the first to sixth semiconductor switching devices 2₁ to 2₆. As a result, the first to sixth semiconductor switching devices 2₁ to 2₆ can be protected more securely, whereby the semiconductor module 1 improves its safety. Since no protection action signal is transmitted through external circuits between the first to sixth control circuits 10₁ to 10₆, the first to sixth control circuits 10₁ to 10₆ can cooperate with each other more rapidly. This can shorten the time required for starting protection actions for all of the first to sixth semiconductor switching devices 2₁ to 2₆.

In the mode where the protection action signal is a binary signal based on whether a voltage is high or low, the I/O circuits 13₁ to 13₆ can be constructed easily. Further, a mode where the lower and higher voltage states (Low- and High-level states) in the binary signal indicate the protected and unprotected states, respectively, can easily employ a so-called wired-OR structure in a signal transmission circuit constituted by the signal line 20 and the I/O circuits 13₁ to 13₆ connected thereby in a bus topology.

In this state, for example, a case where the first to sixth semiconductor switching devices 2₁ to 2₆ are normally switched is defined as a steady state. In the steady state, a signal transmission circuit may be constructed such that, while the voltage state of the I/O circuits 13₁ to 13₆ is set to the Hi-level state by utilizing the level-shift circuit 40 and signal line 20, when the voltage state of the I/O circuit 13ᵢ drops to the Low-level state upon the protection action for the i-th semiconductor switching device 2ᵢ, the voltage of the other I/O circuits also decreases along therewith. Since the protection action signal for the I/O circuit 13ᵢ is transmitted to the other I/O circuits in such a structure, performing the protection action for the i-th switching device 2ᵢ can do the same for the other semiconductor switching devices as well. In the structure in which the voltage drop in the I/O circuit 13ᵢ causes the other I/O circuits to lower the voltage, turning the voltage of the I/O circuit 13ᵢ back to the Hi level can also make the voltage of the other I/O circuits return to the Hi level. That is, after the protection action ends, the steady state comes back, whereby the switching control for the first to sixth semiconductor switching devices 2₁ to 2₆ can resume. Such a structure can be achieved by utilizing transistors for the I/O circuits 13₁ to 13₆, for example.

The mode employing the wired-OR can simplify the structure of the signal transmission circuit including the signal line 20 and I/O circuits 13₁ to 13₆. Since it is easier to adjust the voltage to the low-voltage state (Low-level state), it is preferred for the binary signal to indicate the protection action on-state by the low-voltage state (Low-level state) as exemplified.

The mode where the signal line 20 is connected to the external I/O terminal T_{IO} in the semiconductor module 1 can easily achieve an action stop function for the semiconductor module 1 based on a cause outside of the semiconductor module such as a pushdown of an emergency stop button. Issuing the protection action signal from the external I/O terminal T_{IO} to the outside makes it possible to grasp the state of the semiconductor module 1 easily from the outside thereof.

The present invention is not limited to the embodiment thereof explained in the foregoing but may be modified in various ways within the scope not deviating from the gist thereof. The semiconductor module 1 is not limited to the one having the first to sixth semiconductor switching devices 2₁ to 2₆ as long as it has at least two semiconductor switching devices. For example, the fifth and sixth semiconductor switches 2₅, 2₆ may be omitted. In this case, the semiconductor module 1 functions as a single-phase full-bridge inverter.

In the protection action signal, the higher and lower voltage levels (High- and Low-level states) may indicate the protection action on-state and normal operation, respectively. However, the safety of the semiconductor module 1 improves more when the lower voltage level (Low-level state) indicates the protection action on-state, since this makes even the abnormal state such as a drop in the voltage for driving the first to sixth control circuits 10₁ to 10₆ automatically shift to the protection action.

The connection mode of the semiconductor switching devices illustrated in FIG. 1 is just an example and can be modified appropriately according to their structures.

Constituents and modified modes included in various embodiments and the like exemplified may mutually be combined as appropriate.

What is claimed is:

1. A semiconductor module comprising:
a plurality of semiconductor switching devices;
a plurality of control circuits provided for the respective semiconductor switching devices and adapted to control switching of the semiconductor switching devices corresponding thereto and perform protection actions to stop switching the semiconductor switching devices corresponding thereto falling into a control stop state; and
a signal path connecting the plurality of control circuits to each other and transmitting among the plurality of control circuits a protection action signal indicating whether or not there is the protection action for each of the semiconductor switching devices corresponding to the plurality of control circuits;
wherein any of the plurality of control circuits receiving the protection action signal indicating that another control circuit is in the protection action through the signal path stops switching the semiconductor switching device corresponding thereto.

2. The semiconductor module according to claim 1, wherein each of the plurality of control circuits comprises an I/O circuit adapted to issue the protection action signal to the signal path and receive the protection action signal transmitted through the signal path; and
wherein the signal path connects the I/O circuits of the plurality of control circuits in a bus topology.

3. The semiconductor module according to claim 1, wherein the plurality of semiconductor switching devices include:
first and second semiconductor switching devices, sequentially connected in series between high- and low-voltage-side input terminals, having an intermediate node connected to a first output terminal; and
third and fourth semiconductor switching devices, sequentially connected in series between the high- and low-voltage-side input terminals, having an intermediate node connected to a second output terminal;
wherein the signal path has a first path connecting respective control circuits corresponding to the first and second semiconductor switching devices to each other, a second path connecting respective control circuits corresponding to the third and fourth semiconductor switching devices to each other, and a third path connecting the first and second paths to each other on the side of the respective circuits corresponding to the second and fourth semiconductor switching devices; and
wherein level-shift circuits are provided on the first and second paths so as to be located closer to the respective control circuits corresponding to the first and third semiconductor switching devices than the third path.

4. The semiconductor module according to claim 3, wherein the plurality of semiconductor switching devices further include fifth and sixth semiconductor switching devices, sequentially connected in series between the high- and low-voltage-side input terminals, having an intermediate node connected to a third output terminal;
wherein the signal path further has a fourth path connecting respective control circuits corresponding to the fifth and sixth semiconductor switching devices to each other;
wherein the third path connects the first, second, and fourth paths on the side of the respective control circuits corresponding to the second, fourth, and sixth semiconductor switching devices; and
wherein a level-shift circuit is provided on the fourth path so as to be located closer to the control circuit corresponding to the fifth semiconductor switching device than the third path.

5. The semiconductor module according to claim 1, wherein the protection action signal is a binary signal based on whether a voltage is high or low; and
wherein the lower voltage signal in the binary signal indicates that the protection action is on.

6. The semiconductor module according to claim 1, further comprising an external I/O terminal connecting with one end of the signal path.
